(19) United States
(12) Patent Application Publication
(10) Pub. No.: US 2012/0313120 A1
(43) Pub. Date: Dec. 13, 2012

(54) Method For Depositing A Phosphor Layer On LEDs, And Apparatus Made Thereby

(75) Inventor: Jeffrey Bisberg, Boulder, CO (US)

(73) Assignee: Albeo Technologies, Inc.

(21) Appl. No.: 13/492,393

(22) Filed: Jun. 8, 2012

Related U.S. Application Data
(60) Provisional application No. 61/495,226, filed on Jun. 9, 2011.

(51) Int. Cl. H01L 33/08; H01L 33/44

(52) U.S. Cl. 257/88; 438/29; 257/E33.057; 257/E33.06

(57) ABSTRACT

A method for depositing a phosphor layer on a light-emitting diode (“LED”) chip includes coating at least a light-emitting side of the LED chip with a phosphor-adhesive material, and applying phosphor particles to an exposed surface of the material such that the phosphor layer forms of phosphor particles that adhere to the exposed surface. A method for depositing phosphor layers on each of a plurality of LED chips includes mounting the LED chips to a common substrate, coating at least a light-emitting side of the LED chips with a phosphor-adhesive material, and applying phosphor particles to exposed surfaces of the material such that the phosphor layers form of phosphor particles that adhere to the material. A processed LED chip includes an unpackaged LED chip, a phosphor-adhesive material applied to a light-emitting side of the LED chip, and a phosphor layer formed of phosphor particles adhered to the material.

### CROSS-REFERENCE TO RELATED APPLICATIONS

This application claims priority to U.S. Provisional Patent Application No. 61/495,226, filed 9 Jun. 2011, which is incorporated herein by reference in its entirety.

### BACKGROUND

Light emitting diodes (“LEDs”) typically emit light in a wavelength band related to a semiconductor bandgap voltage; therefore the light often appears to humans to be of one color. “White” LEDs can be produced by fabricating an LED chip that emits visible light towards the blue end of the visible spectrum, and associating a phosphor with the LED chip. The phosphor fluoresces in the presence of the light emitted by the chip, re-emitting some of the light energy at longer wavelengths so that a human sees a light spectrum that approximates white light.

A phosphor is typically applied to an LED by mixing it with a liquid or gel binder, such as epoxy or silicone, which is then applied as a layer to the LED chip, or to a plastic or glass surface of the LED package. This approach poses certain difficulties. One is that phosphor fluorescence efficiency favors use of large phosphor particles, because smaller particles produce higher non-radiative effects (e.g., heat generation instead of fluorescence). However, maintaining a homogeneous mixture of phosphor particles in a liquid or gel favors use of small phosphor particles. For the latter reason, significant effort and expense is sometimes incurred to control phosphor particle size. For example, phosphor particle size may be controlled such that 90% of phosphor particles are within a tolerance of +−30% of some nominal target particle size within the range of approximately 5 to 50 microns.

### SUMMARY

The following embodiments and aspects thereof are described and illustrated in conjunction with systems, tools and methods that are meant to be exemplary and illustrative, not limiting in scope. In certain embodiments, one or more issues and/or limitations associated with the above-described systems and methods have been addressed, while other embodiments are directed to other improvements.

In an embodiment, a method for depositing a phosphor layer on a light-emitting diode (“LED”) chip is provided. The method includes coating at least a light-emitting side of the LED chip with a phosphor-adhesive material, and exposing an exposed surface of the phosphor-adhesive material to phosphor particles such that the phosphor layer forms of phosphor particles that adhere to the exposed surface.

In an embodiment, a method for depositing phosphor layers on each of a plurality of LED chips includes mounting the LED chips to a common substrate, coating at least a light-emitting side of each of the LED chips with a phosphor-adhesive material, and exposing exposed surfaces of the phosphor-adhesive material to phosphor particles such that the phosphor layers form of phosphor particles that adhere to the exposed surfaces.

In an embodiment, a processed LED chip includes an unpackaged LED chip, a phosphor-adhesive material applied to a light-emitting side of the LED chip; and a phosphor layer formed of phosphor particles adhered to the phosphor-adhesive material.

In an embodiment, an LED chip assembly includes a plurality of unpackaged LED chips mounted to a common substrate, a phosphor-adhesive material applied to a light-emitting side of each of the LED chips, and phosphor layers on each of the LED chips, formed of phosphor particles adhered to the phosphor-adhesive material on each of the LED chips.

### BRIEF DESCRIPTION OF THE DRAWINGS

Exemplary embodiments are illustrated in the drawings. It is intended that the embodiments and drawings disclosed herein are illustrative rather than limiting.

FIG. 1 is a flowchart of a phosphor deposition method, in accord with an embodiment.

FIGS. 2A through 2C show a schematic cross-section of an optical assembly that includes mounted LED chips having a phosphor layer deposited thereon, in accord with an embodiment.

FIG. 3 shows a schematic cross-section of another optical assembly that includes mounted LED chips, being lowered into a container of phosphor particles to create a phosphor layer thereon, in accord with an embodiment.

FIG. 4 shows a schematic cross-section of the optical assembly of FIG. 3 with the phosphor layer deposited thereon.

FIGS. 5A and 5B show a schematic cross-section of an optical assembly that includes mounted LED chips 20, having a phosphor layer deposited thereon, in accord with an embodiment.

FIGS. 6A through 6C show a schematic cross-section of another optical assembly that includes mounted LED chips, having multiple phosphor layers and a protective material deposited thereon, in accord with an embodiment.

### DETAILED DESCRIPTION OF THE DRAWINGS

Various modifications to the described embodiments will be readily apparent to those skilled in the art, and the principles herein may be applied to other embodiments. Thus, the present disclosure is not intended to be limited to the embodiments shown, but is to be accorded the widest scope consistent with the principles and features described herein.

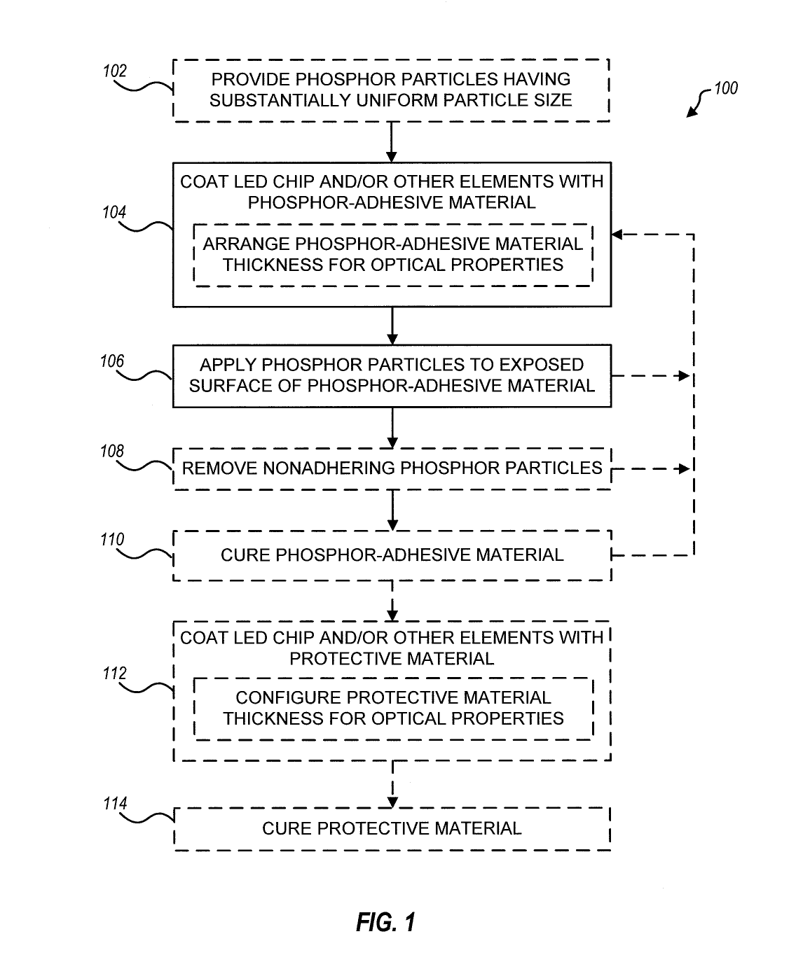

FIG. 1 shows a flowchart of a phosphor deposition method 100. An optional step 102 of method 100 provides a phosphor as phosphor particles. For example, phosphor particles may be provided by purchasing them on the commercial market, or they may be manufactured or modified in form (e.g., to provide a specific particle size range). While step 102 may provide a relatively tight distribution of phosphor particle sizes (e.g., 90% of phosphor particles are within a size range of 50% of a nominal target size), a tight distribution is less critical in step 102 than in prior art phosphor application methods. Also, step 102 may provide phosphor particles that are larger than typically used in the prior art. The nominal target phosphor particle size may be in the range of 20 to 300 microns, and within this range, a sub-range of 40 to 100 microns may provide best results, depending on the specific application.

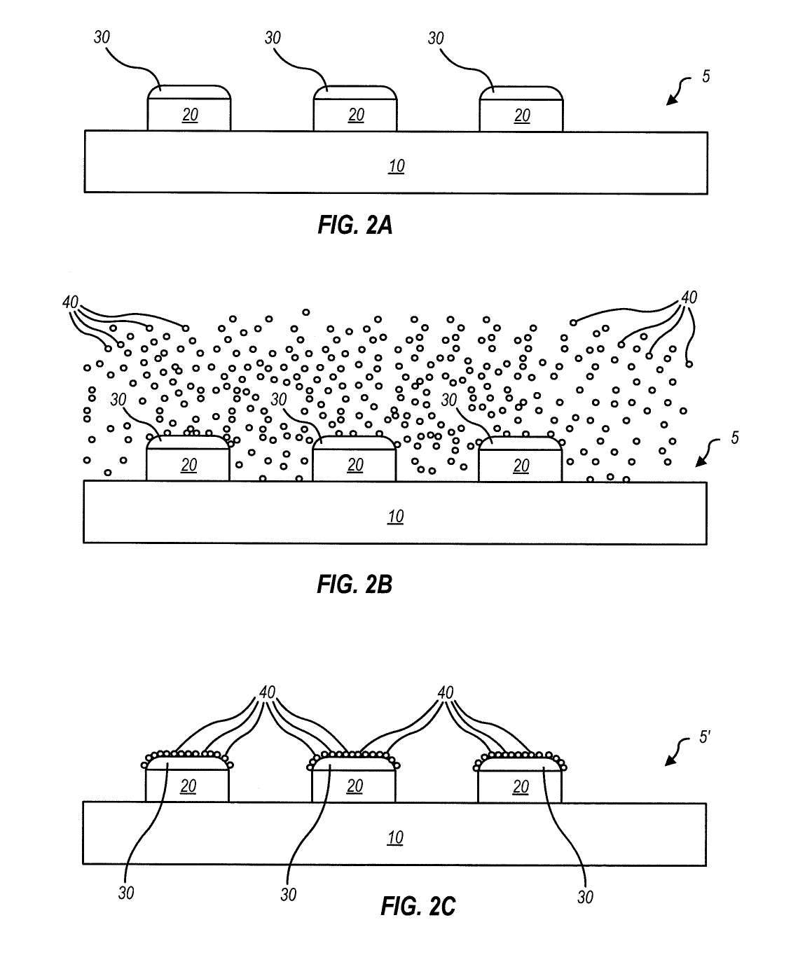

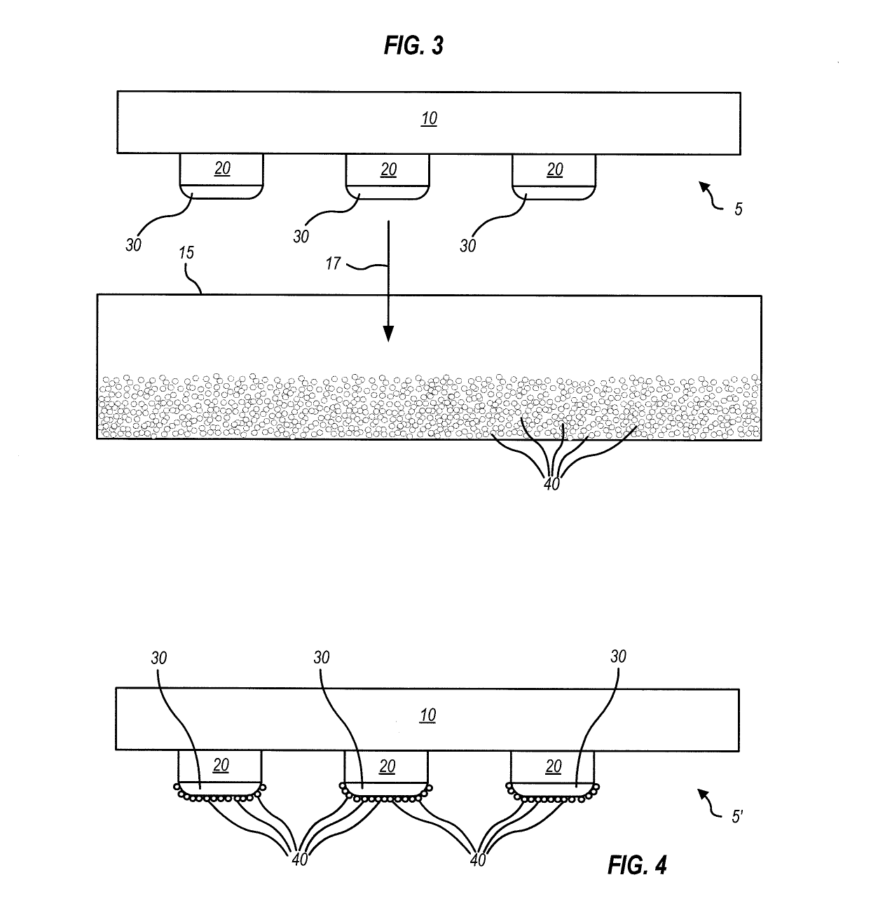

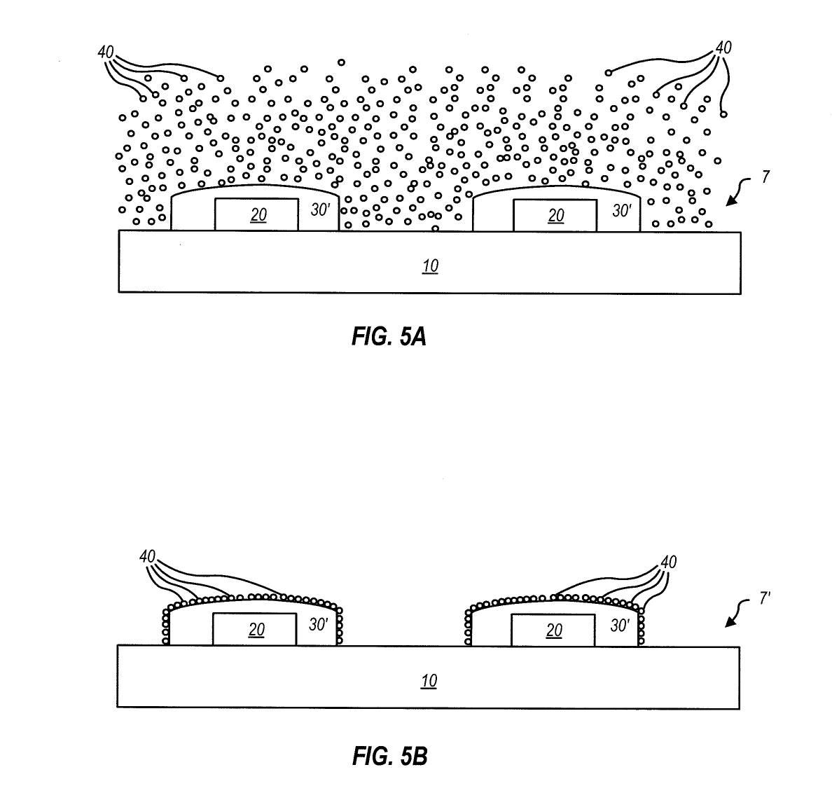

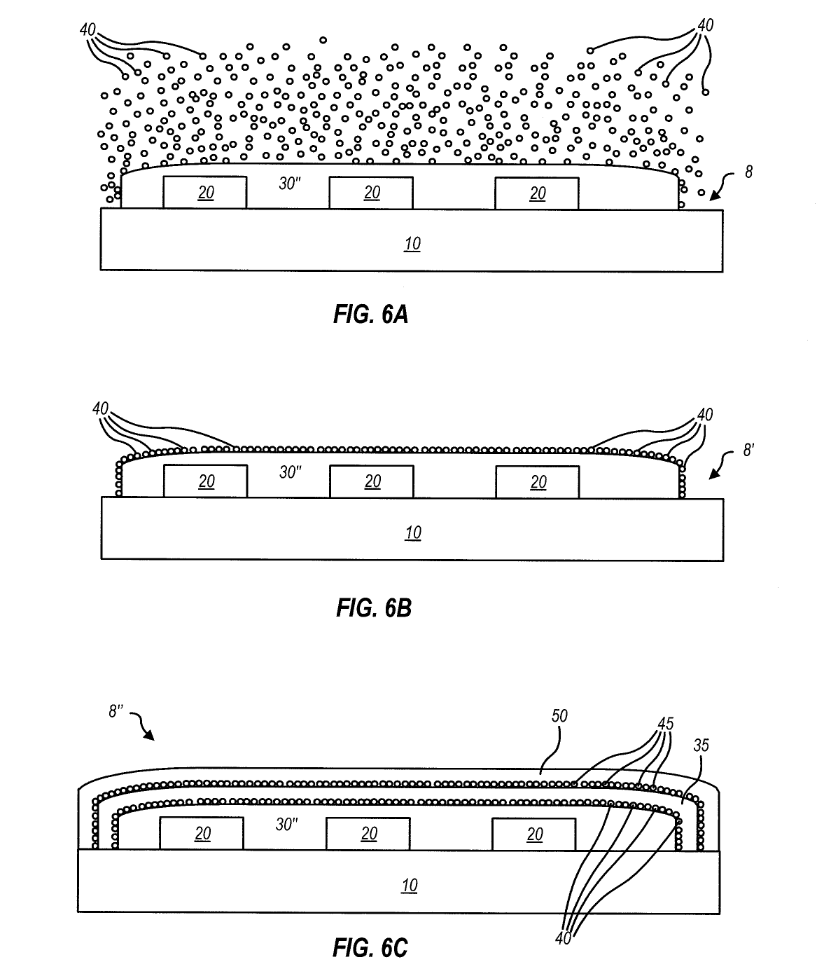

Step 104 coats at least a light-emitting side of the LED chip with a phosphor-adhesive material. In the context of this disclosure, the term “phosphor-adhesive material” means a material capable at least of adhering to a surface to which it is applied, and that presents a surface that the phosphor particles will adhere to. The phosphor-adhesive material may be, for example, a gel, a silicone, or an epoxy. The phosphor-adhesive material may be applied, for example, utilizing conventional techniques such as by emitting it from a nozzle (including utilizing ink jet technology), painting or brushing, or screen printing. Optionally, step 104 may configure thickness and/or refractive index of the phosphor-adhesive material for desired optical properties, such as for example to function as an antireflective coating atop the LED chip. Step 104 may also, in certain embodiments, apply the phosphor-adhesive material to a substrate upon which the LED chip and/or other LED chips are mounted. Examples of step 104 are coating LED chips 20 with phosphor-adhesive materials 30, 30′ or 30″ as shown in FIG. 2A, FIG. 3, FIG. 5A and FIG. 6A.

Step 106 applies phosphor particles to an exposed surface of the phosphor-adhesive material such that a layer of the phosphor particles adheres to the exposed surface to form a phosphor layer. For example, in step 106 the phosphor particles may be poured or dispensed from multiple points (e.g., like orifices of a salt shaker) over the phosphor-adhesive material. The phosphor particles and/or the LED chip with the phosphor-adhesive material may be agitated (e.g., by shaking a fixture or assembly holding the LED chip, or a substrate on which the LED chip and/or other LED chips are mounted, or by movement of air to agitate the particles) so that the phosphor particles have opportunities to stick to the exposed surface. Examples of step 106 performed in this manner include dispensing phosphors over phosphor-adhesive materials as shown in FIG. 2B, FIG. 5A and FIG. 6A. Another way to perform step 106 is to invert the substrate on which the LED chip and/or other chips are mounted, and lower the phosphor-adhesive material into a container of the phosphor particles. In this way of performing step 106, the phosphor particles may be agitated by shaking or blowing so that the particles have ample opportunity to stick to the entire surface of the phosphor-adhesive material. An example of step 106 performed in this way is to lower substrate 10 on which LED chips 20 are mounted and are coated with phosphor-adhesive material 30 into container 15, as shown in FIG. 3.

The density of phosphor particles that stick to the phosphor-adhesive material may be very uniform when applied according to embodiments herein, because such particles may stick to the adhesive but not stick to each other. That is, when step 106 is performed such that the phosphor particles have substantial opportunity to move about on the exposed surface, a phosphor particle will stick to the surface wherever there is an opening large enough to accommodate the particle, but once all such openings have phosphor particles stuck in them, no more phosphor particles will stick. In such a case, the phosphor particles will substantially form a uniform layer one particle thick (e.g., a “particle monolayer”) on the phosphor-adhesive material.

If desired, an optional step 108 may remove phosphor particles that have not adhered to the exposed surface, from the LED chip. For example, step 108 may consist of turning over the LED (and/or a substrate on which the LED chip and/or other LED chips are mounted) such that phosphor particles that did not adhere, simply fall away. Other examples of step 108 include utilizing mechanical agitation, blowing air or another suitable gas, or rinsing with a liquid, to remove phosphor particles that did not adhere to the exposed surface. A further optional step 110 cures the phosphor-adhesive material; examples of step 110 are baking or exposing a phosphor-adhesive material that includes an epoxy to ultraviolet (“UV”) light so that the exposed surface is no longer capable of adhering particles that are not already adhered to the surface.

The sequence of at least steps 104 and 106, (with or without associated steps 102, 108 and 110) may be repeated. This may be desirable to increase a density of the phosphor particles in a path of light emitted from the LED chip, and/or to facilitate deposition of different kinds of phosphors. Further optional steps 112 and 114 provide a layer of protective material, optionally cured in step 114, that chemically passivates or mechanically protects the phosphor layer(s), the underlying phosphor-adhesive materials, the LED chips and/or substrates. Steps 104 and 106 may also be repeated in order to form a multi-layer structure that minimizes internal reflections and maximizes absorption and fluorescence. This is done by controlling thickness and/or refractive index of the phosphor-adhesive layers.

FIGS. 2A through 2C show a schematic cross-section of an optical assembly that includes mounted LED chips 20, having a phosphor layer deposited thereon. FIG. 2A shows assembly 5 having LED chips 20 mounted on a substrate 10. A phosphor-adhesive material 30 is shown as applied to chips 20 (e.g., as in step 104 of method 100, FIG. 1). Thickness and/or refractive index of phosphor-adhesive material 30 may be configured for desired optical properties, such as for example to function as an antireflective coating for LED chips 20. FIG. 2B shows phosphor particles 40 being dispensed over assembly 5 (e.g., as in step 106 of method 100, FIG. 1). Phosphor particles 40 adhere substantially only to phosphor-adhesive material 30, and not to each other, so that a particle monolayer of phosphor particles forms on phosphor-adhesive material 30. FIG. 2C shows optical assembly 5′ having phosphor particles 40 in the particle monolayer on phosphor-adhesive material 30. In FIG. 2C, nonadhering phosphor particles 40 may have been removed (e.g., as in step 108 of method 100, FIG. 1) and phosphor-adhesive material 30 may have been cured (e.g., as in step 110 of method 100, FIG. 1).

FIG. 3 shows a schematic cross-section of another optical assembly that includes mounted LED chips 20, being lowered into a container 15 of phosphor particles 40 to create a phosphor layer thereon. Like FIG. 2A, FIG. 3 shows assembly 5 having LED chips 20 mounted on a substrate 10. A phosphor-adhesive material 30 is shown applied to chips 20 (e.g., as in step 104 of method 100, FIG. 1). FIG. 3 shows assembly 5 inverted and moving in a direction of an arrow 17 into container 15 of phosphor particles 40. As in FIG. 2B, phosphor particles 40 adhere substantially only to phosphor-adhesive material 30, and not to each other, so that a particle monolayer of phosphor particles forms on phosphor-adhesive material 30. FIG. 4 shows optical assembly 5′ having phosphor particles 40 in the particle monolayer on phosphor-adhesive material 30. In FIG. 4, nonadhering phosphor particles 40 have been removed (e.g., as in step 108 of method 100, FIG. 1) and phosphor-adhesive material 30 may have been cured (e.g., as in step 110 of method 100, FIG. 1).

FIGS. 5A and 5B show a schematic cross-section of an optical assembly that includes mounted LED chips 20, having a phosphor layer deposited thereon. FIG. 5A shows assembly 7 having LED chips 20 mounted on a substrate 10. A phosphor-adhesive material 30′ is shown applied to chips 20 (e.g., as in step 104 of method 100, FIG. 1); in FIG. 5A, a portion of the phosphor-adhesive material lies atop LED chips 20 but another portion extends onto a top surface of substrate 10. Providing a portion of phosphor-adhesive material beyond edges of LED chips 20 may provide certain advantages, such as picking up light that scatters from sides of LED chips 20, which might otherwise be lost; also, coating the sides and sealing the interface between substrate 10 and LED chips 20 with phosphor-adhesive material 30′ may improve reliability of the optical assembly. FIG. 5A shows phosphor particles 40 being dispensed over assembly 7 (e.g., as in step 106 of method 100, FIG. 1). Phosphor particles 40 adhere substantially only to phosphor-adhesive material 30′, and not to each other, so that a particle monolayer of phosphor particles forms on phosphor-adhesive material 30′. FIG. 5B shows optical assembly 7′ having phosphor particles 40 in the particle monolayer on phosphor-adhesive material 30′. In FIG. 5B, nonadhering phosphor particles 40 have been removed (e.g., as in step 108 of method 100, FIG. 1) and phosphor-adhesive material 30′ may have been cured (e.g., as in step 110 of method 100, FIG. 1).

FIGS. 6A through 6C show a schematic cross-section of another optical assembly that includes mounted LED chips 20, having multiple phosphor layers and a protective material 50 deposited thereon. FIG. 6A shows assembly 8 having LED chips 20 mounted on a substrate 10, and a phosphor-adhesive material 30″ applied in a layer that covers both chips 20 and portions of substrate 10 (e.g., as in step 104 of method 100, FIG. 1). FIG. 6A also shows phosphor particles 40 being dispensed over assembly 8 (e.g., as in step 106 of method 100, FIG. 1). Phosphor particles 40 adhere substantially only to phosphor-adhesive material 30″, and not to each other, so that a particle monolayer of phosphor particles forms on phosphor-adhesive material 30″. FIG. 6B shows optical assembly 8′ having phosphor particles 40 in a particle monolayer on phosphor-adhesive material 30″ (e.g., after steps 106 of method 100, FIG. 1). FIG. 6C shows optical assembly 8″ having phosphor particles 40 and 45 in particle monolayers on phosphor-adhesive materials 30″ and 35 respectively, that are successively applied (e.g., by repeating steps 104 and 106 of method 100, FIG. 1 upon assembly 8′). In FIGS. 6B and 6C, nonadhering phosphor particles 40 and/or 45 may have been removed (e.g., as in step 108 of method 100, FIG. 1) and phosphor-adhesive materials 30″ and 35 may have been cured (e.g., as in step 110 of method 100, FIG. 1). Assembly 8″ further includes protective layer 50 that is applied and optionally cured (e.g. by steps 112 and 114 of method 100, FIG. 1). Thickness and/or refractive index of protective layer 50 may optionally be configured for desired optical properties, for example to form an antireflective coating for the LED chips.

While the examples described in this disclosure relate to coating LED chips and/or assemblies with phosphor layers, it will be appreciated by those skilled in the art that the methods described and claimed herein may be useful in other phosphor applications. For example, the methods may be utilized to apply phosphors or other particles to diverse surfaces, and the objects formed thereby may be used for any purpose; in particular, these methods could be utilized to apply phosphors to LED chips in standard LED packaging. Application of the methods described herein to such other objects or surfaces may thus be considered to fall within the scope of the disclosed embodiments.

The changes described above, and others, may be made in the phosphor deposition methods described herein without departing from the scope hereof. It should thus be noted that the matter contained in the above description or shown in the accompanying drawings should be interpreted as illustrative and not a limiting sense. The following claims are intended to cover generic and specific features described herein, and should be construed to encompass any statements of the scope of the present method and system, which, as a matter of language, might be said to fall there between.

What is claimed is:

1. A method for depositing a phosphor layer on a light-emitting diode (“LED”) chip, comprising:
coating at least a light-emitting side of the LED chip with a phosphor-adhesive material; and
applying phosphor particles to an exposed surface of the phosphor-adhesive material such that the phosphor layer forms of phosphor particles that adhere to the exposed surface.

2. The method of claim 1, wherein applying comprises applying phosphor particles of a uniform particle size.

3. The method of claim 1, wherein applying comprises forming the phosphor particles substantially as a particle monolayer.

4. The method of claim 1, wherein coating comprises configuring a thickness of the phosphor-adhesive material to impart an optical property to the phosphor-adhesive material.

5. The method of claim 4, wherein the optical property is antireflection.

6. The method of claim 1, further comprising curing the phosphor-adhesive material such that the exposed surface is no longer capable of adhering particles that are not already adhered to the surface.

7. The method of claim 1, further comprising removing phosphor particles that do not adhere to the exposed surface from the LED chip.

8. The method of claim 1, further comprising coating the phosphor layer with a protective material.

9. The method of claim 8, wherein coating the phosphor layer comprises configuring a thickness of the protective material to impart an antireflective property to the protective material.

10. The method of claim 8, wherein coating the phosphor layer with the protective material comprises providing at least one of chemical passivation and mechanical protection for one or both of the phosphor particles and the phosphor-adhesive material.

11. The method of claim 8, wherein the phosphor-adhesive material coating the LED chip is a first phosphor-adhesive material and the protective material is a second phosphor-adhesive material, the method further comprising:
exposing a second exposed surface of the second phosphor-adhesive material to second phosphor particles such that a second phosphor layer forms of the second phosphor particles that adhere to the second exposed surface.

12. A method for depositing phosphor layers on each of a plurality of light-emitting diode (“LED”) chips, comprising:
mounting the LED chips to a common substrate;
coating at least a light-emitting side of each of the LED chips with a phosphor-adhesive material; and
applying phosphor particles to exposed surfaces of the phosphor-adhesive material such that the phosphor layers form of phosphor particles that adhere to the exposed surfaces.

13. A processed light-emitting diode (“LED”) chip, comprising:
an unpackaged LED chip;
a phosphor-adhesive material applied to a light-emitting side of the LED chip; and
a phosphor layer formed of phosphor particles adhered to the phosphor-adhesive material.

14. The processed LED chip of claim 13, the phosphor particles being of uniform particle size.

15. The processed LED chip of claim 13, the phosphor particles substantially forming a particle monolayer.

16. The processed LED chip of claim 13, the phosphor-adhesive material having a thickness configured to impart an antireflective property to the processed LED chip.

17. The processed LED chip of claim 13, the phosphor-adhesive material being cured such that the phosphor-adhesive material is incapable of adhering particles other than particles that form the phosphor layer.

18. The processed LED chip of claim 13, further comprising a protective material coating the phosphor layer.

19. The processed LED chip of claim 18, the phosphor-adhesive material coating the LED chip being a first phosphor-adhesive material and the protective material being a second phosphor-adhesive material, and further comprising a second phosphor layer formed of second phosphor particles adhered to the second phosphor-adhesive material.

20. A light-emitting diode (“LED”) chip assembly, comprising:
a plurality of unpackaged LED chips mounted to a common substrate;
a phosphor-adhesive material applied to a light-emitting side of each of the LED chips, and
phosphor layers on each of the LED chips, formed of phosphor particles adhered to the phosphor-adhesive material on each of the LED chips.
